(19) United States
(12) Patent Application Publication
(10) Pub. No.: US 2022/0171442 A1
(43) Pub. Date: Jun. 2, 2022

(54) LOUVER ASSEMBLIES FOR COMPUTER CASE VENTILATION

(71) Applicant: Hewlett-Packard Development Company, L.P., Spring, TX (US)

(72) Inventor: Joshua Glenn Little, Palo Alto, CA (US)

(73) Assignee: Hewlett-Packard Development Company, L.P., Spring, TX (US)

(21) Appl. No.: 17/419,785

(22) PCT Filed: Aug. 22, 2019
(86) PCT No.: PCT/US2019/047732

§ 371 Date: Jun. 30, 2021

(51) Int. Cl. G06F 1/18; G06F 1/20

(52) U.S. Cl. CPC G06F 1/182; G06F 1/20

(57) ABSTRACT

Examples of a louver assembly for computer case ventilation are described. In some examples, a computer case may include a substructure with vents to allow air intake into the computer case. The computer case may also include louvers attached to the substructure. The vents may be positioned on the substructure such that the louvers occlude visibility into the computer case through the vents from every angle of view outside the computer case.

### BACKGROUND

Computing devices may be housed in a case forming an enclosure for internal components. For example, processors, memory, drives (e.g., optical disk drives, hard drives, etc.), graphics cards, motherboard, power supply, ports and/or other components may be housed within a computer case.

### BRIEF DESCRIPTION OF THE DRAWINGS

Various examples will be described below by referring to the following figures.

FIG. 1 is an elevation view of an example of a computer case with a louver assembly;

FIG. 2 is a cross section view of an example of a louver assembly;

FIG. 3 illustrates an example of a substructure for a louver assembly;

FIG. 4 is a perspective view of a computer case with a louver assembly; and

FIG. 5 is a flow diagram illustrating an example of a method for making a louver assembly.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations in accordance with the description; however, the description is not limited to the examples and/or implementations provided in the drawings.

### DETAILED DESCRIPTION

A computer case may house components used by a computing device. As the computing device operates, heat is generated. Without cooling the internal components of the computing device, the generated heat may damage or degrade the function of the computing device. Airflow through the computing device may be used to cool the computing device.

In some examples of ventilation, holes, slots and stepped shut-off ribs may be used to provide cooling air into the computer case. However, these ventilation approaches allow a viewer to see components within the computer case, which may result in an unsightly appearance. These ventilation approaches also may result in a light leakage from lights (e.g., light emitting diodes (LEDs)) within the computer case. Furthermore, these ventilation approaches may be difficult to clean in the case of dust.

The computer case described herein allows for air exchange through an external surface. The computer case may include a louver assembly that includes a plurality of thermal louvers to allow the intake of the cooling air into a chassis of the computer case. In some examples, the louver assembly may be located on a cosmetic exterior surface (e.g., the front surface) of the computer case. The louver assembly may occlude visibility (line of sight) into the chassis from every angle. The louver assembly may also prevent light leakage from inside the computer case. The louver assembly of the computer case may completely block the light leakage while allowing for easy cleaning of the dust.

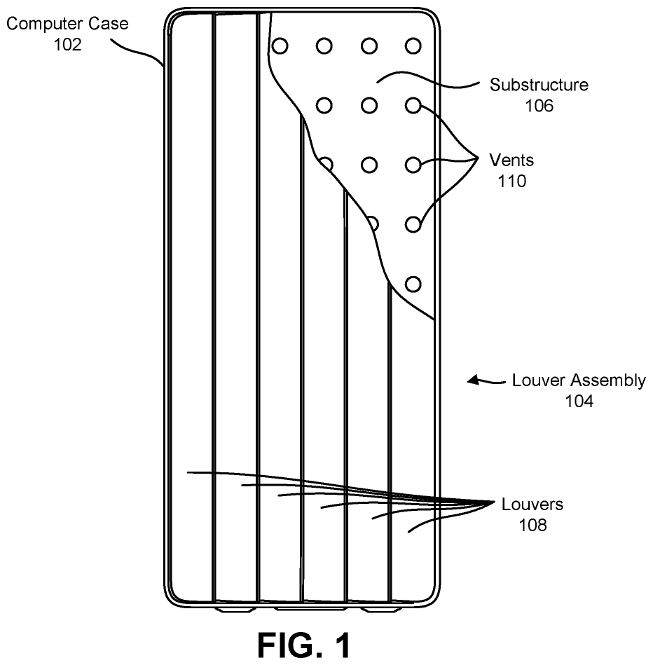

FIG. 1 is an elevation view of an example of a computer case 102 with a louver assembly 104. In the example illustrated in FIG. 1, the computer case 102 may be for a desktop computer. In other examples, the computer case 102 may be used to house a server computer, a laptop computer, a mainframe computer, workstation, minicomputer, etc. The computer case 102 may include additional components (not shown) and/or some of the components described herein may be removed and/or modified without departing from the scope of this disclosure.

In this example, the computer case 102 has a vertical orientation. For instance, the computer case 102 may be implemented as a computer tower. In other examples, the computer case 102 may be implemented with a horizontal orientation.

The computer case 102 may include a louver assembly 104 located on an external surface of the computer case 102. The louver assembly 104 may include a number of louvers 108. In the example illustrated in FIG. 1, the louver assembly 104 includes six louvers 108. It should be noted that any number of louvers 108 may be used.

In this example, the louvers 108 are oriented vertically. In other examples, the louvers 108 may be oriented horizontally or at an angle (e.g., 45 degrees).

In some examples, the louvers 108 may be fabricated from a polymer. For instance, the louvers 108 may be injection molded plastic. In other examples, the louvers 108 may be fabricated from metal.

The louver assembly 104 may also include a substructure 106. In some examples, the substructure 106 may be located behind the louvers 108. The louvers 108 may attach to the substructure 106. In some examples, the louvers 108 may attach to the substructure 106 in an overlapping fashion. It should be noted that in FIG. 1, a cutaway view is used to illustrate the substructure 106 to aid comprehension.

In some examples, the substructure 106 may be fabricated from a polymer. For instance, the substructure 106 may be injection molded plastic. In other examples, the substructure 106 may be fabricated from metal. For instance, the substructure 106 may be formed from sheet metal.

In an example, the substructure 106 may include mounting holes for attaching the louvers 108 on the substructure 106. In this example, the louvers 108 may include snap connectors to attach to the substructure 106 through the mounting holes. In other examples, the louvers 108 may attach to the substructure with mechanical fasteners (e.g., screws) or chemical fasteners (e.g., adhesive).

In an example, the louver assembly 104 (e.g., the substructure 106 and louvers 108) may be located on a front surface of the computer case 102. In other examples, the louver assembly 104 may be located on other surfaces (e.g., side, top, bottom, back) of the computer case 102.

In some examples, the louver assembly 104 may occupy nearly the entire surface of the computer case 102 on which the louver assembly 104 is located. In other examples, the louver assembly 104 may occupy a portion of surface of the computer case 102 on which the louver assembly 104 is located. In the example illustrated in FIG. 1, the front surface of the computer case 102 forms a cavity in which the louver assembly 104 sits.

In some examples, the substructure 106 may attach to the computer case 102. For example, screws may attach the substructure 106 to the computer case 102. In other examples, the substructure 106 may be welded to the computer case 102. In yet other examples, other mechanisms (e.g., snap connectors) may be used to attach the substructure 106 to the computer case 102.

The substructure 106 may include vents 110 to allow air intake into the computer case 102. A vent 110 may be an orifice that allows air to move from the exterior to the interior of the computer case 102. The vents 110 may be holes, slots, square openings, or openings of other shapes. In some examples, the vents 110 may be the same size and shape. In other examples, the vents 110 may have different sizes and/or shapes.

The vents 110 may be positioned on the substructure 106 such that the louvers 108 occlude visibility into the computer case 102 through the vents 110 from every angle of view outside the computer case 102. In other words, the louvers 108 may block the view of the vents 110 to prevent a viewer from seeing the interior of the computer case 102. The vents 110 may be positioned on the substructure 106 to be partially or completely behind a louver 108 when the louver 108 is attached to the substructure 106. Because the vents 110 may be positioned behind the louvers 108, air may follow a curved path around the louvers 108 and through the vents 110 into the computer case 102.

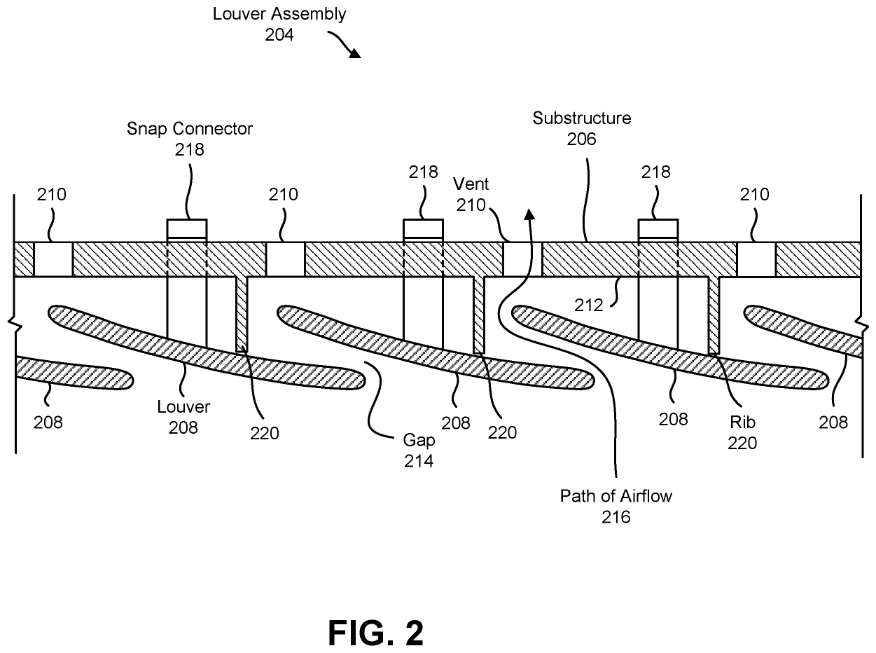

An example of the location of the vents 110 in relation to the louvers 108 is illustrated in FIG. 2. Due to the overlapping nature of the louvers 108, a viewer will not be able to see inside the computer case 102 even if the viewer were to look directly into the gaps between the louvers 108.

The outside surface of the substructure 106 may also occlude visibility into the computer case 102 through the gaps between the louvers 108. In some examples, the portion on the outside surface of the substructure 106 viewable through the gap between louvers 108 may be solid (e.g., may not have visible vents 110 or other openings into the computer case 102). Therefore, when viewed from any angle outside the computer case 102, the outside surface of the substructure 106 may block the view between the louvers 108 into the computer case 102.

In some examples, the louver assembly 104 may block light emanating from within the computer case 102. For example, the substructure 106 and louvers 108 may provide complete line of sight light blockage for a light within the computer case 102. In other words, a light (e.g., an LED) within the computer case 102 may not be directly observable by a viewer through the vents 110.

FIG. 2 is a cross section view of an example of a louver assembly 204. The louver assembly 204 may include a substructure 206 and louvers 208 attached to the outside surface 212 of the substructure 206.

The substructure 206 may include vents 210 to allow air intake into a computer case 102. The vents 210 may be positioned on the substructure 206 such that the louvers 208 occlude visibility into the computer case 102 through the vents 210 from every angle of view through gaps 214 between the louvers 208.

In the illustrated example, the louvers 208 have a curved profile. In this case, the louvers 208 are oriented with a convex bow facing toward the exterior of the computer case 102. In other examples, the louvers 208 may be oriented with a concave bow facing toward the exterior of the computer case 102. In yet other examples, the louvers 208 may have a straight profile.

In this example, the louvers 208 may include a snap connector 218 to attach to the substructure 206. For example, the snap connector 218 may fit within mounting holes on the substructure 206. Tension on the snap connector 218 may hold the louvers 208 in place on the substructure 206. In other examples, other mechanisms may be used to attach the louvers 208 to the substructure 206. For example, in some examples, mechanical fasteners (e.g., screws) or chemical fasteners (e.g., adhesive) may be used to attach the louvers 208 to the substructure 206.

As illustrated in FIG. 2, the airflow may follow a curved path 216 around the louvers 208 and through the vents 210 into the computer case 102. For example, the vents 210 may be located at least partially behind the louvers 208. The air may travel between the gaps 214 of the louvers 208. The path 216 of the air may then curve around the louvers 208 and into the vents 210.

In some examples, the substructure 206 may also include ribs 220 projecting from the outside surface 212 of the substructure 206. The ribs 220 may block line of sight through the louvers 208 and the vents 210 into the computer case 102. For example, the ribs 220 prevent a viewer from seeing into the vents 210 through the gaps 214 between the louvers 208. The ribs 220 may also prevent a viewer from seeing a light (e.g., an LED) within the computer case 102 through the gaps 214 between the louvers 208.

In some examples, a rib 220 may also be used to provide structural support to a louver 208 so that the louver 208 may resist bending. In this case, the rib 220 may be designed to intentionally contact the back side of the louver 208. The ribs 220 may also be used as a bump-stop alignment feature to ensure that all of the louvers 208 are properly aligned during assembly.

In some examples, the ribs 220 may be formed (e.g., molded, machined) on the substructure 206. In other examples, the ribs 220 may be attached (e.g., welded, bonded, screwed on) the substructure 206.

In some examples, the outside surface 212 of the substructure 206 may be a cosmetic surface. For example, the outside surface 212 (including the ribs 220, in some examples) may be processed (e.g., painted, anodized, textured) to achieve a cosmetic finish. In some examples, the louvers 208 may also be processed to achieve a cosmetic finish. In some examples, the cosmetic finish of the louvers 208 may match the cosmetic finish of the substructure 206. In this manner, the appearance of the substructure 206 may be obscured from view from the exterior of the computer case 102. In other words, the substructure 206 may appear to blend in with the louvers 208.

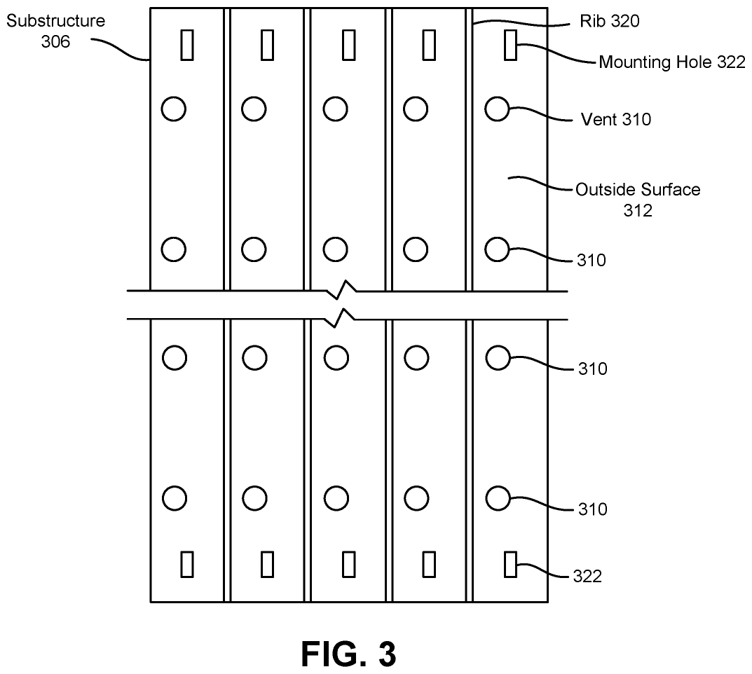

FIG. 3 illustrates an example of a substructure 306 for a louver assembly. In this example, the substructure 306 has a number of vents 310. As described above, the vents 310 may be positioned on the substructure 306 such that louvers 108 attached to the substructure 306 (not shown) occlude visibility into the computer case 102 through the vents 310.

In some examples, the substructure 306 may include mounting holes 322 for attaching the louvers 108 on the substructure 306. In this example, the mounting holes 322 are shaped as rectangular slots to receive a snap connector 218 on a louver 108. It should be noted that the mounting holes 322 may have other shapes or orientations.

In some examples, the substructure 306 may include ribs 320 (also referred to as walls or fins). The ribs 320 may project out from the outside surface 312 of the substructure 306. In some examples, the ribs 320 may have a rectangular cross section. In other examples, the ribs 320 may have a tapered cross section. In yet other examples, the cross section of the ribs 320 may be other shapes (e.g., curved).

The ribs 320 may be sized to project to a location at or near a back side of a louver 108 attached to the substructure 306. In some examples, the curvature of the louver 108 (when attached to the substructure 306) may conceal the leading edge of a rib 320.

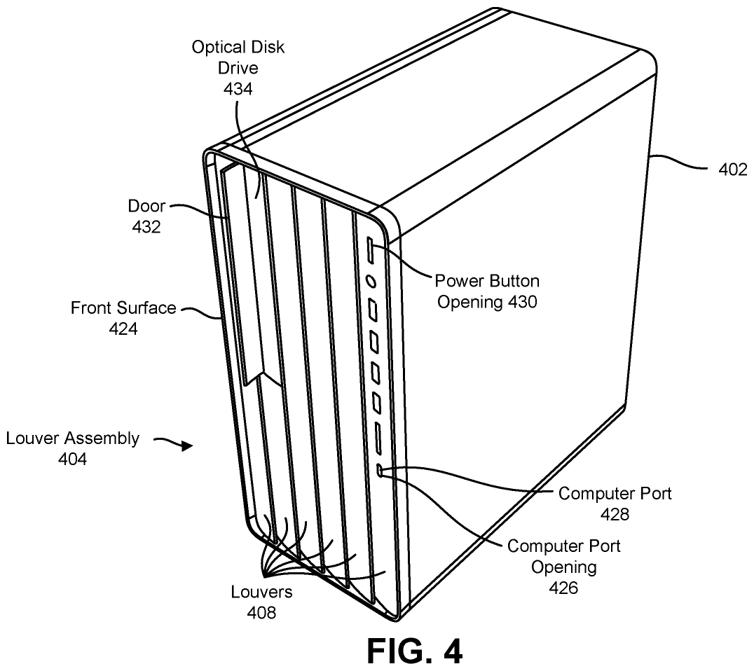

FIG. 4 is a perspective view of a computer case 402 with a louver assembly 404. The louver assembly 404 may include a number of louvers 408 attached to a subassembly (not shown). In some examples, when attached to the computer case 402, the subassembly may be obscured behind the louvers 408.

In this example, the louver assembly 404 is installed on a front surface 424 of the computer case 402. In other examples, the louver assembly 404 may be installed on other surfaces of the computer case 402.

In some examples, a louver 408 (referred to herein as a first louver for ease of explanation) may include an opening 426 to interface with a computer port 428. For example, the computer port opening 426 may permit access to a computer port 428 located within the computer case 402. In some examples, the first louver 408 may include multiple openings 426 to interface with multiple computer ports 428.

In some examples, a louver 408 (e.g., the first louver or another louver) may include an opening 430 to interface with a power button. For example, a user may press the power button through the power button opening 430 located on the louver 408.

In some examples, a louver 408 (referred to herein as a second louver for ease of explanation) may include a door 432 to provide an opening for an optical disk drive 434. The door 432 may match the profile of the second louver 408 when the door 432 is in a closed position. The door 432 may move to allow access to the optical disk drive 434. For example, the door 432 may rotate to allow access to the optical disk drive 434.

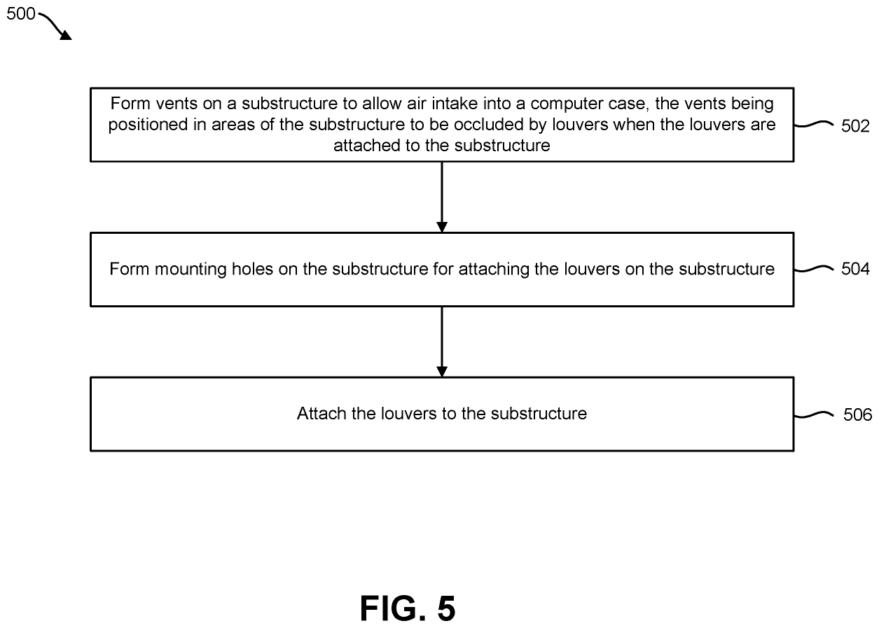

FIG. 5 is a flow diagram illustrating an example of a method 500 for making a louver assembly 104 for computer case ventilation. Vents 110 may be formed 502 on a substructure 106 to allow air intake into a computer case 102. The vents 110 may be positioned in areas of the substructure 106 to be occluded by louvers 108 when the louvers 108 are attached to the substructure 106. The vents 110 may be holes, slots, square openings, or openings of other shapes. In some examples, the vents 110 may be the same size and shape. In other examples, the vents 110 may have different sizes and/or shapes.

Mounting holes 322 may be formed 504 on the substructure 106 for attaching the louvers 108 on the substructure 106. In some examples, the mounting holes 322 may be shaped and sized to receive snap connectors 218 on the louvers 108.

In some examples, ribs 220 projecting from an outside surface 212 of the substructure 106 may be formed to block line of sight through the louvers 108 and the vents 110 into the computer case 102. The ribs 220 may be sized to project to a location at or near a back side of a louver 108 attached to the substructure 106.

The louvers 108 may be attached 506 to the substructure 106. The louvers 108 may include snap connectors 218 to attach to the substructure 106 through the mounting holes 322. When attached, the louvers 108 may occlude visibility into the computer case 102 through the vents 110 from every angle of view through gaps 214 between the louvers 108.

It should be noted that while various examples of systems and methods are described herein, the disclosure should not be limited to the examples. Variations of the examples described herein may be implemented within the scope of the disclosure. For example, functions, aspects, or elements of the examples described herein may be omitted or combined.

1. A computer case, comprising:
a substructure with vents to allow air intake into the computer case; and
louvers attached to the substructure, the vents being positioned on the substructure such that the louvers occlude visibility into the computer case through the vents from every angle of view outside the computer case.

2. The computer case of claim 1, wherein an outside surface of the substructure occludes visibility into the computer case through gaps between the louvers.

3. The computer case of claim 2, wherein the substructure further comprises ribs projecting from the outside surface to block line of sight through the louvers and the vents into the computer case.

4. The computer case of claim 1, wherein air follows a curved path around the louvers and through the vents into the computer case.

5. The computer case of claim 1, wherein the substructure further comprises mounting holes for attaching the louvers on the substructure.

6. The computer case of claim 5, wherein the louvers comprise snap connectors to attach to the substructure through the mounting holes.

7. The computer case of claim 1, wherein the substructure and louvers are located on a front surface of the computer case.

8. The computer case of claim 1, wherein the substructure and louvers provide complete line of sight light blockage for a light within the computer case.

9. A louver assembly, comprising:
a substructure comprising:
vents to allow air intake into a computer case; and
an outside surface oriented toward an exterior of the computer case when the substructure is installed on the computer case; and
louvers attached to the outside surface of the substructure, the vents being positioned on the substructure such that the louvers occlude visibility into the computer case through the vents from every angle of view through gaps between the louvers.

10. The louver assembly of claim 9, wherein a first louver comprises an opening to interface with a computer port.

11. The louver assembly of claim 10, wherein the first louver further comprises an opening to interface with a power button.

12. The louver assembly of claim 9, wherein a second louver comprises a door to provide an opening for an optical disk drive.

13. The louver assembly of claim 12, wherein the door matches a profile of the second louver when the door is in a closed position.

14. A method for making a louver assembly, comprising:
forming vents on a substructure to allow air intake into a computer case, the vents being positioned in areas of the substructure to be occluded by louvers when the louvers are attached to the substructure;
forming mounting holes on the substructure for attaching the louvers on the substructure; and
attaching the louvers to the substructure, the louvers comprising snap connectors to attach to the substructure through the mounting holes, the louvers occluding visibility into the computer case through the vents from every angle of view through gaps between the louvers.

15. The method of claim 14, further comprising forming ribs projecting from an outside surface of the substructure to block line of sight through the louvers and the vents into the computer case.
